(19) United States
(12) Patent Application Publication
(10) Pub. No.: US 2015/0145067 A1
(43) Pub. Date: May 28, 2015

(54) FIN STRUCTURE

(71) Applicant: UNITED MICROELECTRONICS CORP., Hsin-Chu City (TW)

(72) Inventors: Chin-I Liao, Tainan City (TW); Chun-Yu Chen, Taichung City (TW)

(73) Assignee: UNITED MICROELECTRONICS CORP., Hsin-Chu City (TW)

(21) Appl. No.: 14/092,942

(22) Filed: Nov. 28, 2013

(51) Int. Cl. H01L 29/78

(52) U.S. Cl. CPC H01L 29/7851; H01L 29/7846
USPC 257/401

(57) ABSTRACT

A fin structure includes a substrate and a fin disposed on a top surface of the substrate. The fin has a height. An epitaxial structure surrounds the fin and the epitaxial structure has a top point which is the farthest point on the epitaxial structure away from the top surface of the substrate. There is a distance between the top point and the top surface of the substrate. A rational number of the distance to the height is not less than 7.

### BACKGROUND OF THE INVENTION

1. Field of the Invention

This invention relates generally to semiconductor devices, and more particularly to a fin structure of a fin field-effect transistor (FinFET) device.

2. Description of the Prior Art

As integrated circuits become downscaled, the corresponding requirements also increase. Modern transistors need to have high drive currents even as their dimensions become smaller. This has led to the development of Fin field-effect transistors (FinFETs).

A typical FinFET is fabricated with a fin extending from a substrate. The channel of the FinFET is formed therein and a gate structure intersects the fin.

Although FinFETs can satisfy the requirements of small size and high current, their inherent complexity requires different manufacturing techniques from those used to manufacture planar transistors. Stress-memorization techniques (SMTs) are techniques which are applied to conventional planar MOS devices. By carefully controlling the amorphization and re-crystallization of a planar device channel, the effects of a stress force applied to the device will remain even after the stressor is removed. The stress effects improve charge mobility through the channel, thereby improving device performance.

In order to increase current flow in FinFETs, a method of applying stress to a FinFET is also needed.

### SUMMARY OF THE INVENTION

In accordance with one aspect of the present invention, a fin structure includes a substrate, and a fin disposed on a top surface of the substrate, wherein the fin has a height. An epitaxial structure surrounds the fin, wherein the epitaxial structure has a middle line extending in a vertical direction, wherein the middle line separates the epitaxial structure symmetrically, the middle line starts from a top surface of the epitaxial structure and ends at a top surface of the substrate, and the middle line has a length. It should be noted that a rational number of the length to the height is not less than 7.

In accordance with another aspect of the present invention, a fin structure comprises: a substrate and a fin disposed on a top surface of the substrate, wherein the fin has a height. An epitaxial structure surrounds the fin, wherein the epitaxial structure has a top point which is the farthest point on the epitaxial structure from the top surface of the substrate in a vertical direction. There is a distance between the top point and the top surface of the substrate. A rational number of the distance to the height is not less than 7.

In accordance with yet another aspect of the present invention, a fin structure comprises: a substrate and a fin disposed on a top surface of the substrate, wherein the fin has a height. An epitaxial structure surrounds the fin, wherein the epitaxial structure has a top surface which is the farthest plane on the epitaxial structure from the top surface of the substrate in a vertical direction. There is a distance between the top surface of the fin and the top surface of the substrate. A rational number of the distance to the height is not less than 7.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a perspective view of a FinFET according to an embodiment of the present invention.

FIG. 2 is a cross-sectional view taken along line A-A in FIG. 1.

FIG. 3 is a cross-sectional view taken along line B-B in FIG. 1.

FIG. 4 to FIG. 10 are cross-sectional views and perspective views of intermediate stages in the manufacturing of a FinFET device.

FIG. 11 shows two TEM pictures of fin structures.

### DETAILED DESCRIPTION

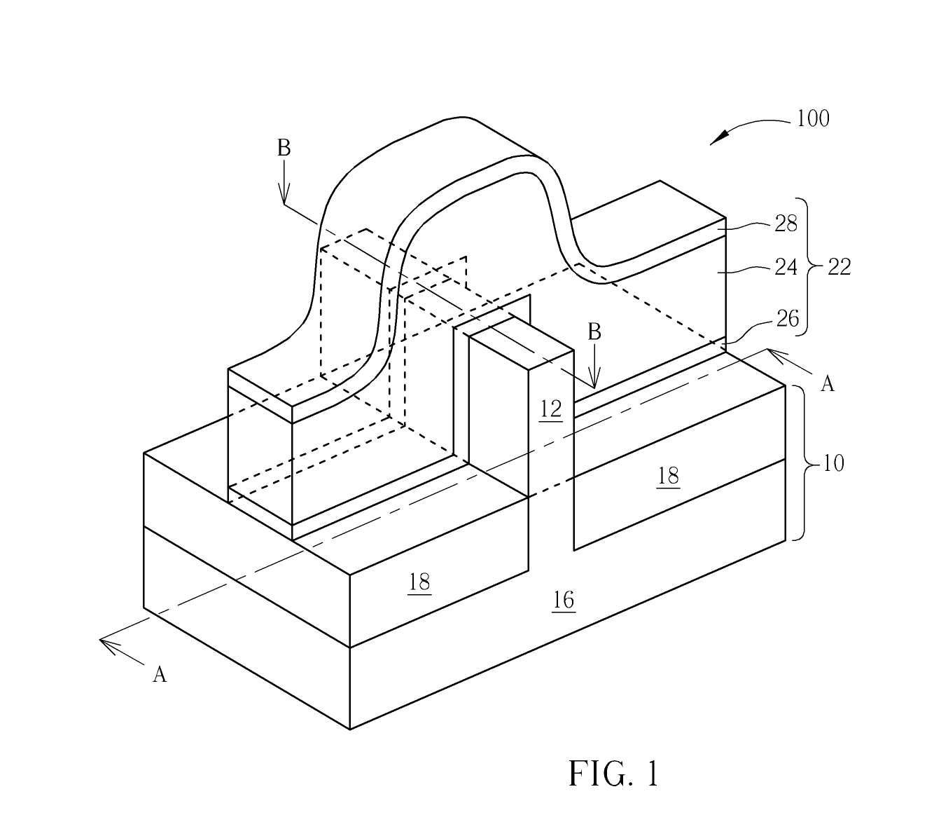

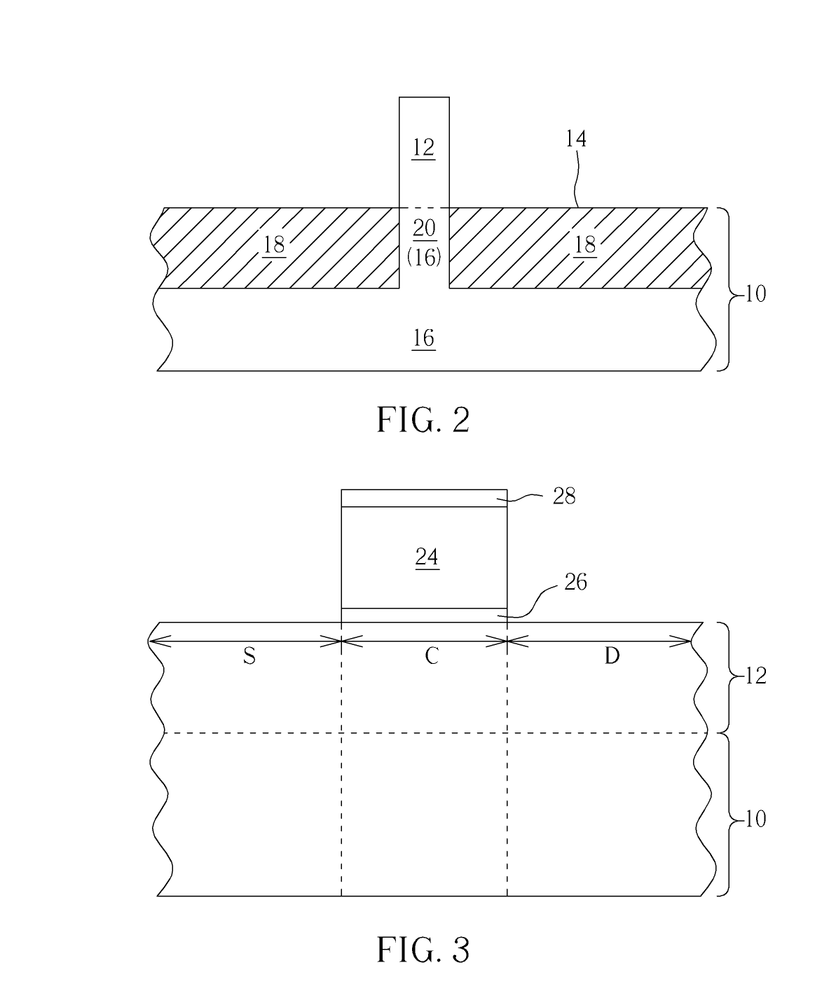

FIG. 1 illustrates a perspective view of a FinFET according to an embodiment of the present invention. FIG. 2 is a cross-sectional view taken along line A-A in FIG. 1. FIG. 3 is a cross-sectional view taken along line B-B in FIG. 1.

As shown in FIG. 1, a FinFET device 100 is provided. FinFET device 100 refers to any fin-based transistor, such as a fin-based, multi-gate transistor. In the following depicted embodiment, the FinFET device may be a p-type FinFET device or an n-type FinFET device.

Please refer to FIG. 2. As illustrated in the diagram, the FinFET device 100 includes a substrate 10, and a fin 12 disposed on a top surface 14 of the substrate 10. The substrate 10 includes a base semiconductor layer 16 with a protrusion 20. Two isolation layers 18 are disposed on the base semiconductor layer 16 and sandwich the protrusion 20. The isolation layers 18 may be shallow trench isolations. The top surfaces of the isolation layers 18 define the top surface 14 of the substrate 10. The extension of the top surface 14 of the isolation layer 18 in the base semiconductor layer 16 defines the top surface (shown by dashed lines) 14 of the substrate 10 in the base semiconductor layer 16. More specifically, the top surface 14 of the substrate 10 in the base semiconductor layer 16 is the top surface of the protrusion 20.

The base semiconductor layer 16 may be a bulk silicon substrate, a germanium substrate, a gallium arsenide substrate, a silicon germanium substrate, an indium phosphide substrate, a gallium nitride substrate or a silicon carbide substrate.

As shown in FIG. 1, the FinFET device 100 further includes a gate structure 22. The gate structure 22 traverses the fin 12. The gate structure 22 may include a gate dielectric layer 26 and a gate electrode 24. The gate dielectric layer 26 may be silicon oxide, high-k dielectric material, other suitable dielectric material, or combinations thereof. The gate electrode 24 may be made of polysilicon, metal, other conductive materials, or combinations thereof. The gate electrode 24 may be formed in a gate first or gate last process. The gate structure 22 may include numerous other layers. For example, a capping layer 28 can be disposed on the gate structure 22.

As shown in FIG. 3, a source region S and a drain region D are defined on the fin 12. A channel C is defined between the source region S and the drain region D. FIG. 2 illustrates the sectional view of the drain region D of the fin 12. Because the source region S and the drain region D of the fin 12 have the same structure, and the same fabricating steps will be implemented in the source region S as in the drain region D afterwards, only the sectional view of the drain region D is shown in the following description for the sake of brevity.

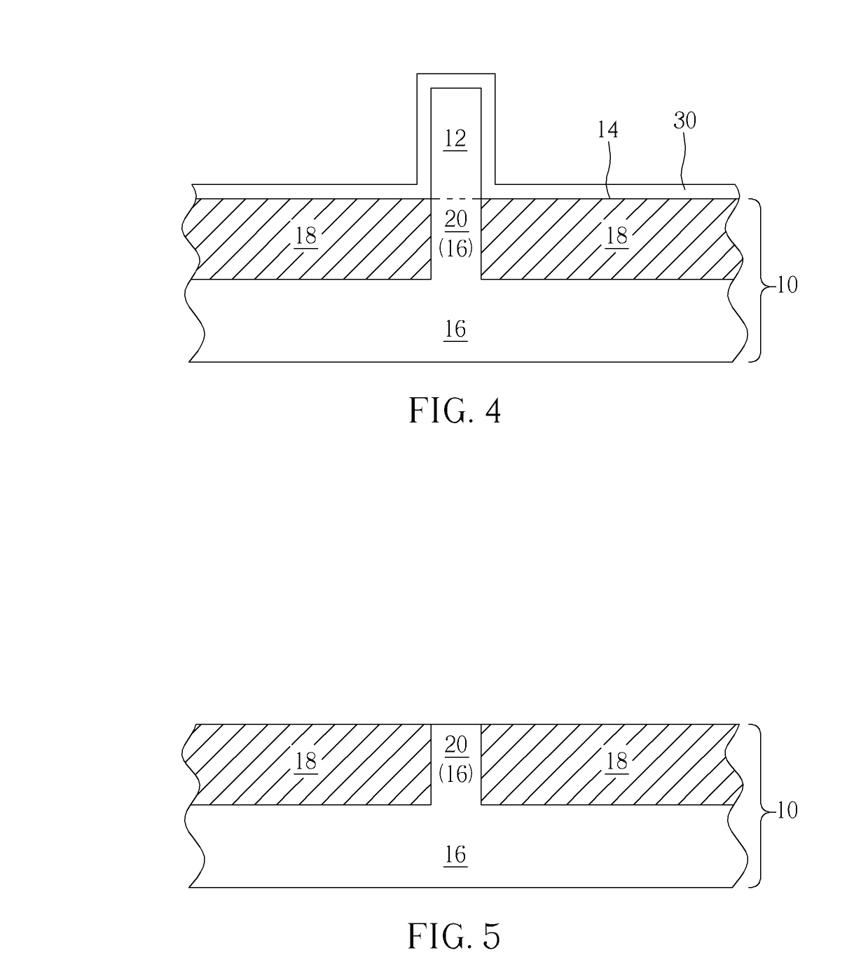

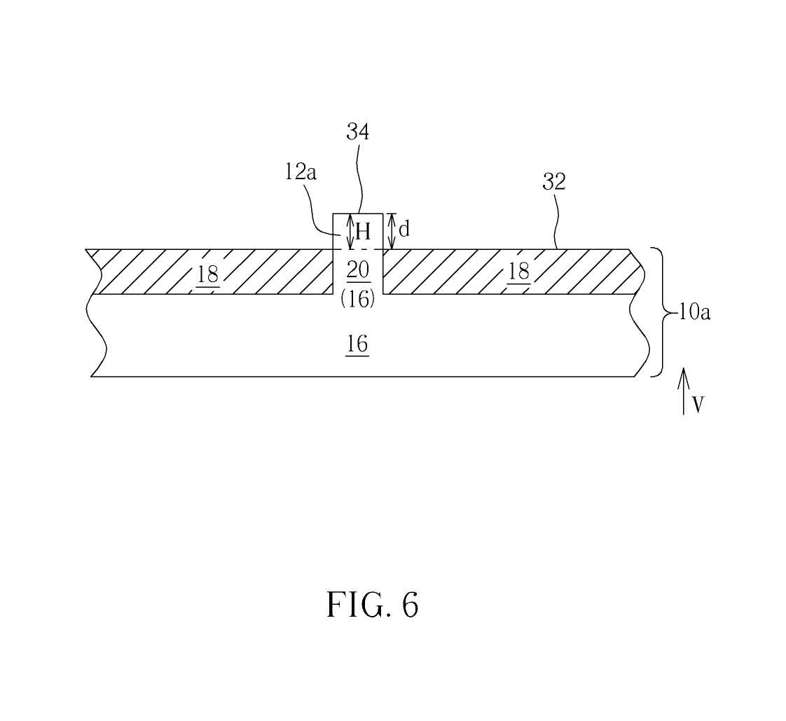

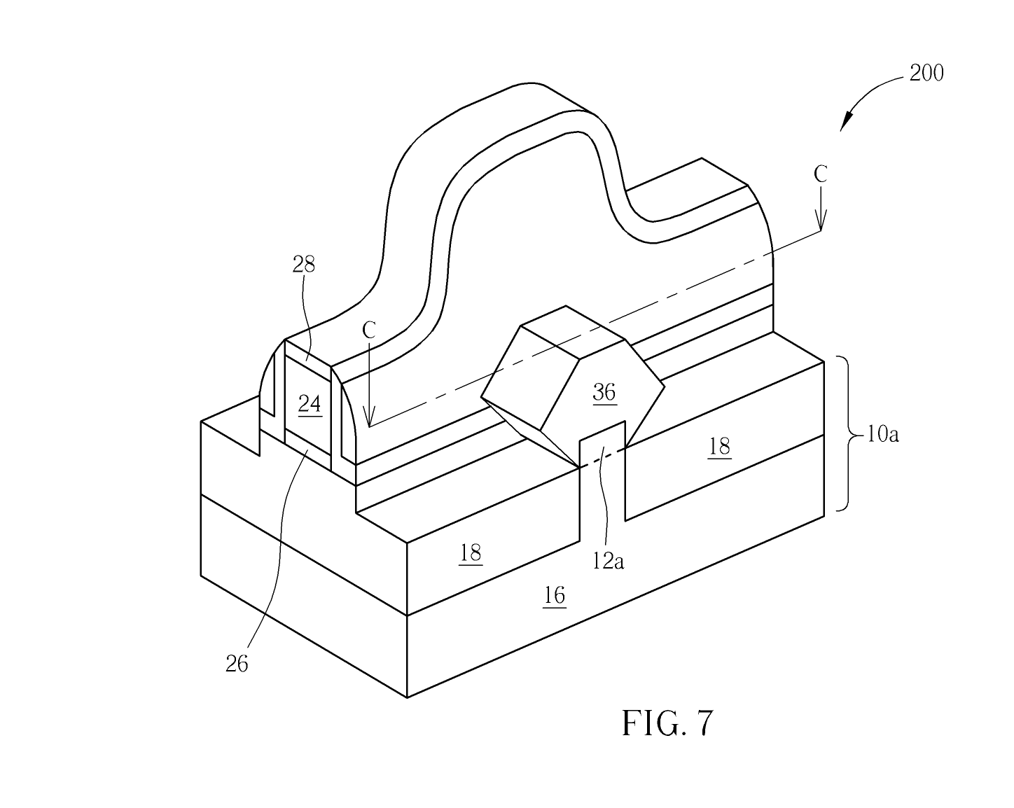

FIG. 4 to FIG. 10 are cross-sectional views and perspective views of intermediate stages in the manufacturing of a FinFET device. As shown in FIG. 4, a spacer material 30 is conformally disposed on the fin 12 and the gate structure 22 (not shown). The spacer material 30 on the gate structure 22 may then be etched to form a spacer (not shown). As shown in FIG. 5, the source region S (not shown) and the drain region D of the fin 12 are removed, and the spacer material 30 on the source region S and the drain region D is also removed. After removing the source region S and the drain region D of the fin 12, the top surface of the protrusion 20 is exposed. When removing the source region S and the drain region D, a protective layer (not shown) may cover the gate structure 22 and the spacer to prevent the gate structure 22 and the spacer from being affected by the removing step. In this way, the spacer material 30 on the fin 12, and the isolation layers 18 not covered by the gate structure 22 are exposed through the protective layer. Therefore, the spacer material 30 on the fin 12 can be removed together with source region S and the drain region D of the fin 12. As shown in FIG. 6, the exposed isolation layers 18 are partly removed. More specifically, a depth d of the exposed isolation layers 18 are removed, and part of the protrusion 20 of the base semiconductor substrate 16 extrudes over a top surface 32 of the isolation layer 18. The depth d is less than 70 angstroms. The removing of the isolation layers 18 can be performed by a SiCoNi process or dilute Hydrofluoric acid. The SiConi process is a remote plasma assisted dry etch process which involves the simultaneous exposure of a substrate to H₂, NF₃ and NH₃ plasma by-products. Remote plasma excitation of the hydrogen and fluorine species allows plasma-damage-free substrate processing. After removing part of the isolation layers 18, the substrate 10 becomes substrate 10a. The top surfaces 32 of the isolation layers 18 define a top surface 32 of the substrate 10a. The extension of the top surface 32 of the isolation layer 18 in the base semiconductor layer 16 defines the top surface 32 of the substrate 10a in the base semiconductor layer 16 which is shown by dashed lines.

The extruding part of the base semiconductor layer 16 above the top surface 32 of the substrate 10a is designated as a fin 12a. The fin 12a has a height H, and the height H is defined as a distance between the top surface 32 of the substrate 10a and a top surface 34 of the fin 12a in a vertical direction V. The vertical direction V is perpendicular to the top surface 32 of the substrate 10a. Therefore, the height H equals to the depth d. This means the height H is also less than 70 angstroms.

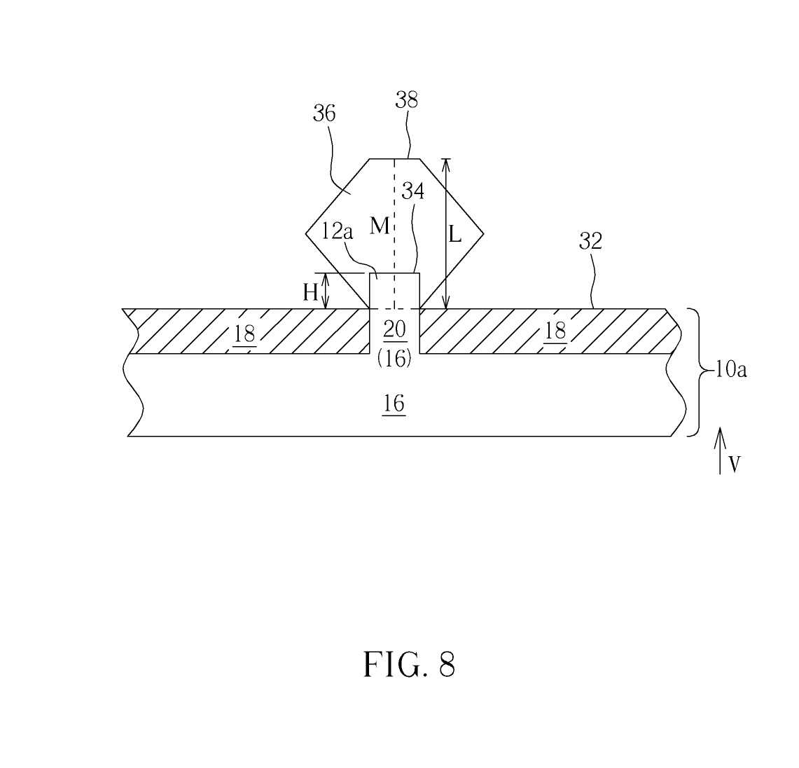

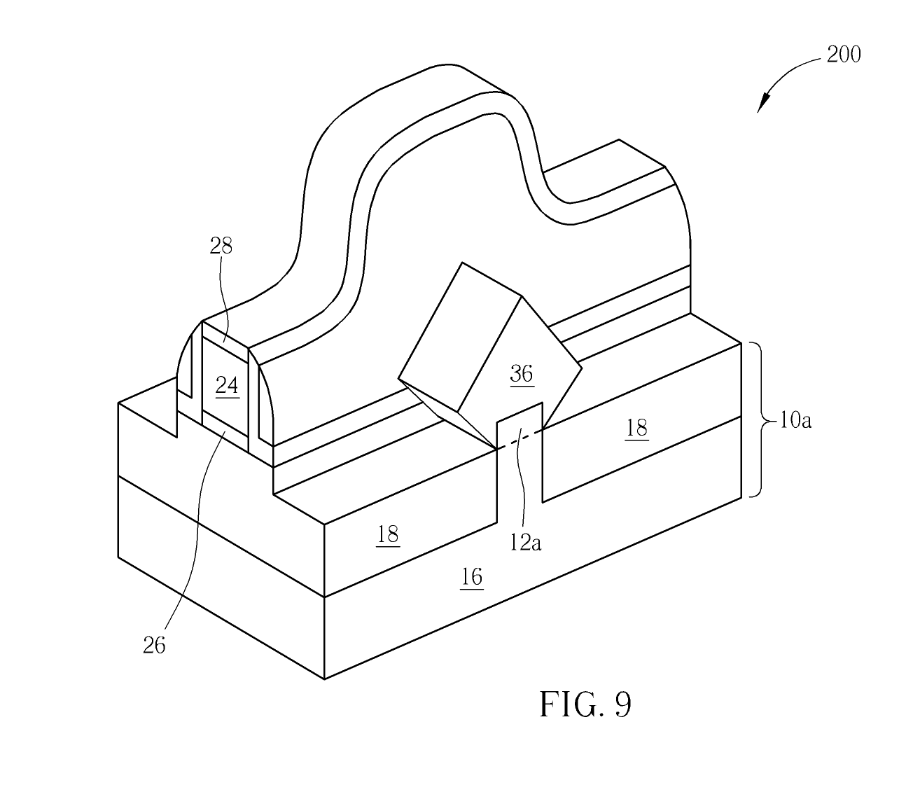

FIG. 7 shows a perspective view of a FinFET fabricated by a method according to a first embodiment of the present invention. FIG. 8 is a cross-sectional view taken along line C-C in FIG. 7.

As shown in FIG. 7 and FIG. 8, an epitaxial structure 36 grows epitaxially on the fin 12a. The epitaxial structure 36 surrounds the fin 12a. In the first preferred embodiment, the epitaxial structure 36 has a plane top surface 38. The epitaxial structure 36 has a middle line M which extends in the vertical direction V and separates the epitaxial structure 36 symmetrically. The middle line M starts from the top surface 38 of the epitaxial structure 36, and ends at the top surface 32 of the substrate 10a. The middle line M has a length L. It is noteworthy that a rational number of the length L to the height H is not less than 7. The rational number is the quotient of length L divided by height H. Furthermore, the top surface 38 of the epitaxial structure 36 described above is the farthest plane of the epitaxial structure 36 located away from the top surface 32 of the substrate 10a in the vertical direction V. A distance L is disposed between the top surface 38 of the epitaxial structure 36 and the top surface 32 of the substrate 10a. The distance L is entirely overlapped with the length L of the middle line M. In other words, the distance L equals the length L of the middle line M. Therefore, a rational number of the distance L to the height H is also not less than 7. Furthermore, the epitaxial structure 36 below the top surface 34 of the fin 12a grows in a lattice direction of <110>, and the epitaxial structure 36 above the top surface 34 of the fin 12a grows in lattice directions of <111> and <100>.

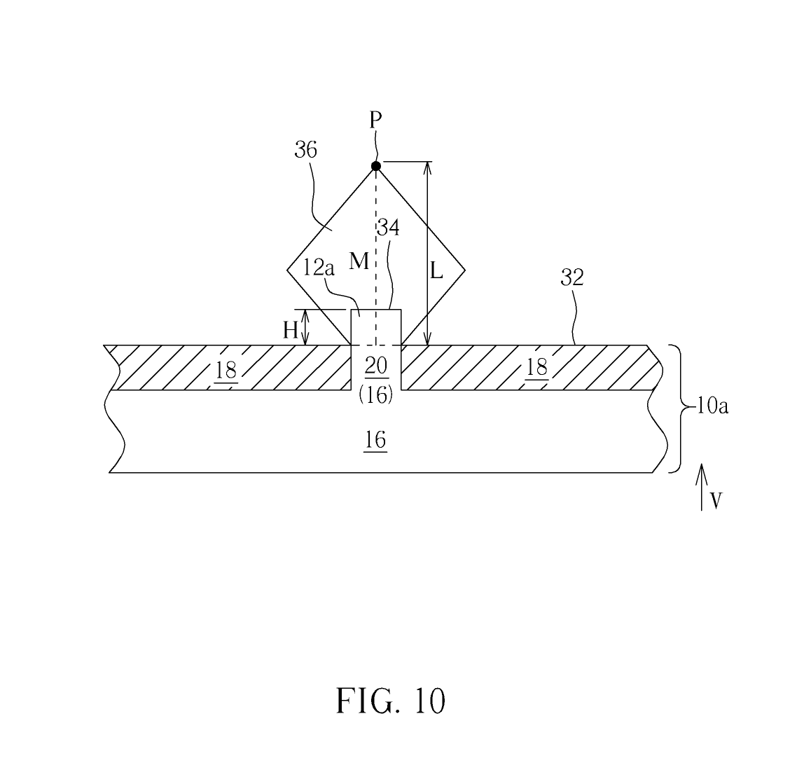

FIG. 9 illustrates a perspective view of a FinFET fabricated by a method according to a second embodiment of the present invention. FIG. 10 is a cross-sectional view taken along line D-D in FIG. 9.

As shown in FIG. 9 and FIG. 10, an epitaxial structure 36 grows epitaxially on the fin 12a. The differences between the epitaxial structures 36 in the first embodiment and in the second embodiment are that the epitaxial structure 36 in the second embodiment has a top point P as the farthest point of the epitaxial structure 36 located away from the top surface 32 of the substrate 10a in the vertical direction V. The epitaxial structure 36 in the first embodiment has a top surface 36 (refer to FIG. 8) as the farthest plane away from the top surface 32 of the substrate 10a. In FIG. 9 and FIG. 10, other elements are substantially the same as those in the first embodiment illustrated in FIG. 7 and FIG. 8, and are therefore denoted by the same reference numerals.

Please refer to FIG. 9 and FIG. 10. The epitaxial structure 36 surrounds the fin 12a. A middle line M extends in the vertical direction V and separates the epitaxial structure 36 symmetrically. The middle line M starts from the top point P of the epitaxial structure 36, and ends at the top surface 32 of the substrate 10a. The middle line M has a length L. It is noteworthy that a rational number of the length L to the height H is not less than 7. The rational number is the quotient of length L divided by height H. Furthermore, there is a distance L between the top point P of the epitaxial structure 36 and the top surface 32 of substrate 10a. The distance L is entirely overlapped with the length L of the middle line M. In other words, the distance L equals the length L of the middle line M. Therefore, a rational number of the distance L to the height H is also not less than 7. Furthermore, the epitaxial structure 36 below the top surface 34 of the fin 12a grows in a lattice direction of <110>, and the epitaxial structure above the top surface 34 of the fin 12a grows in lattice directions of <111> and <100>. The epitaxial structure 36 may be silicon germanium if the FinFET device is p-type, and may be silicon carbide if the FinFET device is n-type.

After the epitaxial structure 36 is formed, either by the method illustrated in FIG. 7 and FIG. 8 or by the method illustrated in FIG. 9 and FIG. 10, implantations are performed to introduce p-type or n-type impurities into the epitaxial structure 36 to form a source and a drain. Then, the protective layer covering the gate structure 22 and the spacer can be removed. At this point the FinFET device 200 of the present invention is completed.

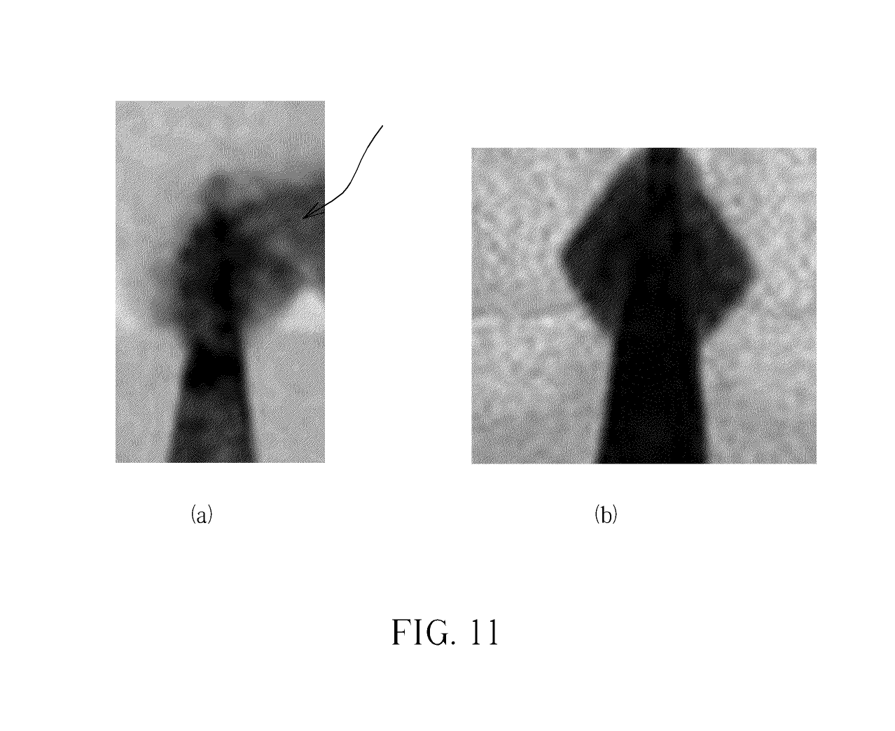

FIG. 11 shows two TEM pictures of fin structures. The fin structure in example (a) is formed by a conventional method. As shown in example (a), the fin structure has a dislocation indicated by an arrow. The fin structure in example (b) is formed by the method provided in the present invention. The fin structure in example (b) has an ideal profile without dislocations.

Advantageously, the epitaxial structure of the fin structure formed by using the method of the present invention can prevent dislocation. In addition, the short channel effect of the FinFET device can be reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fin structure, comprising:
a substrate;
a fin disposed on a top surface of the substrate, wherein the fin has a height; and
an epitaxial structure surrounding the fin, wherein the epitaxial structure has a middle line extending in a vertical direction, the middle line separates the epitaxial structure symmetrically, the middle line starts from a top surface of the epitaxial structure and ends at a top surface of the substrate, and the middle line has a length;
wherein a rational number of the length to the height H is not less than 7.

2. The fin structure of claim 1, wherein the substrate comprises a base semiconductor layer and two isolation layers, the base semiconductor layer has a protrusion and the two isolation layers sandwich the protrusion.

3. The fin structure of claim 1, wherein the height is defined as a distance between the top surface of the substrate and a top surface of the fin in the vertical direction.

4. The fin structure of claim 1, wherein the height is not more than 70 angstroms.

5. The fin structure of claim 1, wherein the vertical direction is perpendicular to the top surface of the substrate.

6. The fin structure of claim 1, wherein the epitaxial structure below a top surface of the fin grows in a lattice direction of <110>, and the epitaxial structure above the top surface of the fin grows in lattice directions of <111> and <100>.

7. A fin structure, comprising:
a substrate;
a fin disposed on a top surface of the substrate, wherein the fin has a height;
an epitaxial structure surrounding the fin, wherein the epitaxial structure has a top point which is the farthest point on the epitaxial structure away from the top surface of the substrate in a vertical direction; and
a distance between the top point and the top surface of the substrate;
wherein a rational number of the distance to the height is not less than 7.

8. The fin structure of claim 7, wherein the substrate comprises a base semiconductor layer and two isolation layers, the base semiconductor layer has a protrusion and the two isolation layers sandwich the protrusion.

9. The fin structure of claim 7, wherein the height is defined as a distance between the top surface of the substrate and a top surface of the fin.

10. The fin structure of claim 7, wherein the height is not more than 70 angstroms.

11. The fin structure of claim 7, wherein the vertical direction is perpendicular to the top surface of the substrate.

12. The fin structure of claim 7, wherein the epitaxial structure below a top surface of the fin grows in a lattice direction of <110>, and the epitaxial structure above the top surface of the fin grows in lattice directions of <111> and <100>.

13. A fin structure, comprising:
a substrate;
a fin disposed on a top surface of the substrate, wherein the fin has a height;
an epitaxial structure surrounding the fin, wherein the epitaxial structure has a top surface which is the farthest plane on the epitaxial structure away from the top surface of the substrate in a vertical direction; and
a distance between the top surface of the fin and the top surface of the substrate;
wherein a rational number of the distance to the height is not less than 7.

14. The fin structure of claim 13, wherein the substrate comprises a base semiconductor layer and two isolation layers, the base semiconductor layer has a protrusion and the two isolation layers sandwich the protrusion.

15. The fin structure of claim 13, wherein the height is defined as a distance between the top surface of the substrate and a top surface of the fin.

16. The fin structure of claim 13, wherein the height is not more than 70 angstroms.

17. The fin structure of claim 13, wherein the vertical direction is perpendicular to the top surface of the substrate.

18. The fin structure of claim 13, wherein the epitaxial structure below a top surface of the fin grows in a lattice direction of <110>, and the epitaxial structure above the top surface of the fin grows in lattice directions of <111> and <100>.
